(19) United States
(12) Patent Application Publication
(10) Pub. No.: US 2025/0308585 A1
(43) Pub. Date: Oct. 2, 2025

(54) BTI-AWARE MEMORY CIRCUITS AND METHODS FOR OPERATING THE SAME

(71) Applicant: Taiwan Semiconductor Manufacturing Company, Ltd., Hsinchu (TW)

(72) Inventors: Wei-Yu Lin, Hsinchu City (TW); Li-Yue Huang, Hsinchu City (TW); Ming-Hung Chang, Hsinchu City (TW); Ching-Wei Wu, Hsinchu City (TW)

(73) Assignee: Taiwan Semiconductor Manufacturing Company, Ltd., Hsinchu (TW)

(21) Appl. No.: 18/789,274

(22) Filed: Jul. 30, 2024

Related U.S. Application Data
(60) Provisional application No. 63/571,054, filed on Mar. 28, 2024.

(51) Int. Cl. G11C 11/419; G11C 11/418

(52) U.S. Cl. CPC G11C 11/419; G11C 11/418

(57) ABSTRACT

A memory circuit includes a memory array including memory cells, wherein each of memory cells is accessible through a plurality of access lines. The memory circuit includes a delay circuit configured to receive a first clock pulse and delay the first clock pulse as a second clock pulse, wherein the second clock pulse immediately follows the first clock pulse. The memory circuit includes a logic gate configured to receive the first clock pulse and the second clock pulse, and provide a pre-charge signal for pre-charging the plurality of access lines based on the first and second clock pulses. The delay circuit includes a plurality of inverters and a plurality of transistors, such that a time difference between a first transition edge of the first clock pulse and a second transition edge of the second clock pulse is extended in accordance with an increasing age of the memory circuit.

### CROSS-REFERENCE TO RELATED APPLICATION

This application claims priority to and the benefit of U.S. Provisional Application No. 63/571,054, filed Mar. 28, 2024, entitled “SIGNAL GENERATION CIRCUIT DESIGN,” which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example block diagram of a memory circuit, in accordance with some embodiments.

FIG. 2 illustrates a schematic diagram of a timing controller and a pre-charge circuit of the memory circuit of FIG. 1, in accordance with some embodiments.

FIG. 3 illustrates an example circuit diagram of the timing controller of FIG. 2, in accordance with some embodiments.

FIG. 4 illustrates another circuit diagram of the timing controller of FIG. 2, in accordance with some embodiments.

FIG. 5 illustrates yet another circuit diagram of the timing controller of FIG. 2, in accordance with some embodiments.

FIG. 6 illustrates yet another circuit diagram of the timing controller of FIG. 2, in accordance with some embodiments.

FIG. 7 illustrates yet another circuit diagram of the timing controller of FIG. 2, in accordance with some embodiments.

FIG. 8 illustrates yet another circuit diagram of the timing controller of FIG. 2, in accordance with some embodiments.

FIG. 9 illustrates yet another circuit diagram of the timing controller of FIG. 2, in accordance with some embodiments.

FIG. 10 illustrates yet another circuit diagram of the timing controller of FIG. 2, in accordance with some embodiments.

FIG. 11 illustrates yet another circuit diagram of the timing controller of FIG. 2, in accordance with some embodiments.

FIG. 12 illustrates yet another circuit diagram of the timing controller of FIG. 2, in accordance with some embodiments.

FIG. 13 illustrates example waveforms of various signals when operating the timing controller of FIG. 2 implemented as any of the circuit diagrams shown in FIGS. 3-12, in accordance with some embodiments.

FIG. 14 illustrates an example flow chart of a method for operating a memory circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Integrated circuits commonly include Static Random Access Memory (SRAM) circuits to provide on-chip data storage. An SRAM circuit is typically configured to meet specific design requirements associated with the surrounding circuitry attached to the SRAM circuit. One common type of SRAM circuit provides one port for either read or write access to data stored within the SRAM circuit. The address inputs to such a circuit are typically shared for both read and write access. Another common type of SRAM circuit, referred to as a two-port SRAM circuit, provides two ports for accessing data stored within the SRAM circuit. Two-port SRAM circuits usually restrict all read accesses to one port and all write accesses to the second port. Each port of a two-port SRAM circuit is typically capable of asynchronous, independent access to data stored within the SRAM circuit, allowing the two-port SRAM circuit to be incorporated in a range of different applications with different usage models.

The two-port SRAM circuit allows designers to achieve system performance levels that are generally higher than those possible using only one-port SRAM circuits. However, for a given number of storage bits, existing two-port SRAM circuits require approximately double the area of one-port SRAM circuits. Thus, integrated circuits where instances of SRAM circuits are a significant portion of the overall die area, using two-port SRAM circuits can be an extremely expensive design option.

One way to reduce the die area expense associated with using two-port SRAM circuits involves substituting each two-port SRAM cell with a one-port SRAM cell (e.g., a six-transistor SRAM cell) that operates with sequential read access and write access. For example, one read access and one write access are possible per cycle of a clock signal, allowing the SRAM circuit to present two external ports, each capable of performing one transaction per clock cycle. In general, two clock pulses are generated based on the single clock signal, one configured for the read access and the other configured for the write access. Such an SRAM circuit is sometimes referred to as double-pumped SRAM circuit.

However, a double-pumped SRAM circuit commonly suffers from aging of the SRAM circuit, sometimes referred to as a Bias Temperature Instability (BTI) effect. In accordance with aging of an SRAM circuit (or its transistor components), the absolute value of a threshold voltage of the transistor increases, which causes the transistors harder to turn on resulting in lower conduction current. This consequently leads to various issues for the double-pumped SRAM circuit, for example, during a transition mode of the SRAM circuit. During such a phase, bit lines (BLs) of the SRAM circuit are typically configured to be pre-charged to VDD or a high logic state. As the BTI effect is becoming more significant, a window of this pre-charging phase is typically compressed, e.g., having a delayed rising edge and/or an advanced falling edge. The existing technology does not seem to include any circuit or component configured for tracking such a BTI effect. Thus, the existing double-pumped SRAM circuits have not been entirely satisfactory in certain aspects.

The present disclosure provides various embodiments of a memory circuit that incudes various components to real-time track aging effects, if any, present in the memory circuit. As such, even with the aging effect, the memory circuit, as herein disclosed, can be advantageously immune from the compressed pre-charging window. In various embodiments, the memory circuit, as herein disclosed, is a double-pumped Static Random Access Memory (SRAM) circuit that can be operated sequentially with a first (e.g., read) access and a second (e.g., write) access. The first access and the second access can be activated by a first clock pulse and a second clock pulse, respectively. However, it should be understood that the disclosed memory circuit is not limited to such an SRAM circuit. Based on the first clock pulse and the second clock pulse, a pre-charge signal, configured for pre-charging bit lines of the SRAM circuit, can be generated. For example, such a pre-charge signal can have a pulse width defined (e.g., confined) by a falling edge of the first clock pulse and a rising edge of the second clock pulse. The pulse width of the pre-charging signal is sometimes referred to as a pre-charging window.

In one aspect, the disclosed SRAM circuit can include a number of always-on p-type transistors and/or a number of always-on n-type transistors coupled to a delay chain or delay circuit of the SRAM circuit. The delay chain can be formed by a plural number of inverter stages. The p-type transistors can be respectively coupled to even-numbered stages, and the n-type transistors can be respectively coupled tot odd-numbered stages. In another aspect, the delay chain of the disclosed SRAM circuit can include two additional transistors gated by a control signal. The control signal can be configured such as to alter the polarity of an output of each inverter stage. In yet another aspect, the SRAM circuit includes one or more always-on transmission gates coupled to the delay chain. With any of the implementations, the rising edge of the second clock pulse following the first pulse can be delayed, as long as one or more of the transistors of the SRAM circuit show a BTI effect. Consequently, the pre-charging window can be advantageously increased when a BTI effect is present, which allows the adjusted pre-charging window to track the BTI effect, or more specifically, to compensate for the BTI effect.

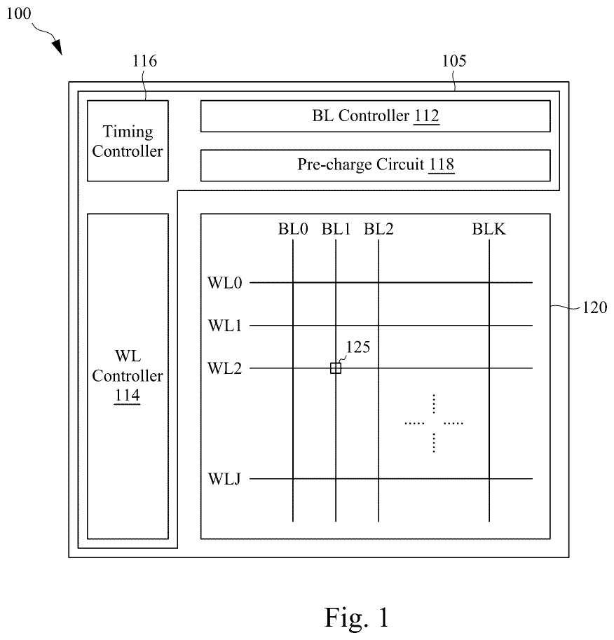

FIG. 1 illustrates a schematic diagram of a memory system or circuit 100, in accordance with various embodiments. The memory system 100 is implemented as an integrated circuit. As shown in the illustrated example of FIG. 1, the memory system 100 includes a memory controller 105 and a memory array 120. The memory array 120 may include a number of storage circuits, memory cells, memory bits, or bit cells 125 arranged in two-dimensional or three-dimensional arrays. Each of the memory cells 125 is accessible through a plural number of access lines. For example, each of the memory cells 125 may be connected to at least a corresponding word line WL and a corresponding pair of bit lines BL. Each of the word lines WL and bit lines BL may include any conductive (e.g., metal) material. For example, each of the word lines WL and bit lines BL can be implemented as one or more metal lines. The memory controller 105 may write data to or read data from the memory array 120 according to electrical signals through word lines WL and bit lines BL. In other embodiments, the memory system 100 includes more, fewer, or different components than shown in FIG. 1, while remaining within the scope of the present disclosure.

The memory array 120 is a hardware component that stores data. In various embodiments, the memory array 120 is embodied as a semiconductor memory device. The memory array 120 includes a number of storage circuits or memory cells 125. In some embodiments, the memory array 120 includes word lines WL0, WL1 . . . WLJ, each extending in a first direction and bit lines BL0, BL1 . . . BLK, each extending in a second direction. The word lines WL and the bit lines BL may be conductive metals or conductive rails. Each memory cell 125 is connected to a corresponding word line WL and a corresponding pair of bit lines BL, and can be operated according to voltages or currents through the corresponding word line WL and the corresponding pair of bit lines BL. Each memory cell 125 may be a Static Random-Access Memory (SRAM) cell. For example, the memory cell 125 can be implemented as a six-transistor (6T) SRAM cell or otherwise one-port SRAM cell. However, it should be understood that the memory cell 125 can be implemented in any of various other memory configurations, while remaining within the scope of the present disclosure. In some embodiments, the memory array 120 includes additional lines (e.g., sense lines, reference lines, reference control lines, power rails, etc.).

The memory controller 105 is a hardware component that controls operations of the memory array 120. In some embodiments, the memory controller 105 includes a bit line controller 112, a word line controller 114, a timing controller 116, and a pre-charge circuit 118. In one configuration, the word line controller 114 is a circuit that provides a voltage or current signal through one or more word lines WL of the memory array 120. In one aspect, the bit line controller 112 is a circuit that provides a voltage or current signal through one or more bit lines BL of the memory array 120 and senses a voltage or current from the memory array 120 through the one or more bit lines BL. In various embodiments, the timing controller 116 is a circuit that provides two clock pulses for a read access and a following write access (or a write access and a following read access) on the memory array 120, respectively. The timing controller 116 can include various components to track a BTI effect present in the memory array 120 so as to adjust (e.g., delay) the timing of a rising edge of the following clock pulse, which can advantageously widen the pulse window of a pre-charging signal. The timing controller 116 can provide the pre-charge circuit 118 with the pre-charging signal, and the pre-charge circuit 118 can utilize the pre-charging signal to pre-charge the bit lines BL to a high logic state (e.g., VDD) during a phase when the memory array 120 is not being read or written (e.g., between the two clock pulses). Further, the timing controller 116 can provide the word line controller 114 and the bit line controller 112 with control signals or clock signals to synchronize operations of the bit line controller 112 and the word line controller 114.

The bit line controller 112 may be connected to the bit lines BL of the memory array 120, and the word line controller 114 may be connected to the word lines WL of the memory array 120. In one example, to write data to a memory cell 125, the word line controller 114 is configured to apply a voltage or current signal (sometimes referred to as a WL signal) to the memory cell 125 through a corresponding word line WL connected to the memory cell 125, and the bit line controller 112 is configured to apply a voltage or current signal corresponding to data to be stored to the memory cell 125 through a pair of bit lines BL connected to the memory cell 125. To read data from a memory cell 125, the word line controller 114 is configured to apply a WL signal to the memory cell 125 through a corresponding word line WL connected to the memory cell 125, and the bit line controller 112 is configured to sense a voltage or current corresponding to data stored by the memory cell 125 through a bit line connected to the memory cell 125. In some embodiments, the memory controller 105 includes more, fewer, or different components than shown in FIG. 1, while remaining within the scope of the present disclosure.

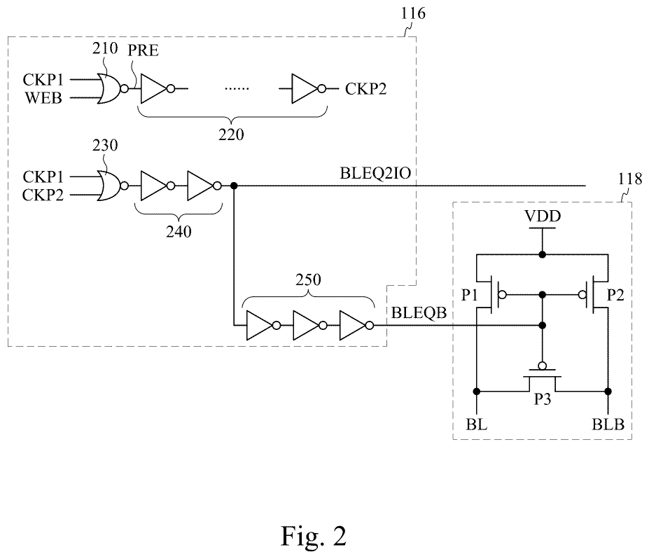

FIG. 2 illustrates an example schematic diagram of a portion of the memory controller 105 of FIG. 1, in accordance with various embodiments of the present disclosure. For example, the schematic diagram of FIG. 2 includes circuit implementations of the timing controller 116 and the pre-charge circuit 118, respectively. In various embodiments, the timing controller 116 is configured to generate a second clock pulse based on a first clock pulse, and provide a pre-charge signal based on the first and second clock pulses; and the pre-charge circuit 118 is configured to receive the pre-charge signal (or its logically inverted version) to pre-charge the bit lines of a corresponding memory array (e.g., 120). Details of the timing controller 116 and the pre-charge circuit 118 will be provided below. It should be understood that the schematic diagram of FIG. 2 is provided for illustrative purposes, and thus, each of the timing controller 116 and the pre-charge circuit 118 can be configured otherwise while remaining within the scope of the present disclosure.

As shown, the timing controller 116 includes a first logic gate 210, a delay chain (or delay circuit) 220, a second logic gate 230, a plurality of first buffers 240, and a plurality of second buffers 250. The first logic gate 210, which may be implemented as a two-input NOR gate, can receive a write enable bar (WEB) signal and a first clock pulse (CKP1), and perform a NOR function on its inputs to provide an intermediate (PRE) signal. In some embodiments, the WEB signal may be provided at logic 1 when the memory array 120 is configured with a standby mode; and the WEB signal may be provided at logic 0 when the memory array 120 is configured with a write mode (generally referred to as an operation mode). The PRE signal then propagates through the delay chain 220, which may include an even number of inverter stages, and is outputted as a second clock pulse (CKP2). In some embodiments, the CKP1 may be generated based on the transition edge (e.g., the rising edge) of a corresponding clock signal, and the CKP2 can immediately follow the CKP1. As such, in some examples, the CKP1 and CKP2 may correspond to (e.g., fall within) one half of the cycle of the corresponding clock signal.

The second logic gate 230, which may be implemented as a two-input NOR gate, can receive the CKP1 and the CKP2, and perform a NOR function on its inputs to provide a pre-charge (BLEQ2IO) signal through the first buffers 240. In some embodiments, the number of the first buffers 240 may be an even number. Due to the intentional delay, the CKP2 follows the CKP1 with a time difference. A pulse of the BLEQ2IO signal (e.g., at logic 1) can be generated (e.g., NOR'ed) from the time difference. Stated another way, between the CKP1 and CKP2 where CKP1 and CKP2 are both at logic 0, the NOR gate 230 can generate the pulse of the BLEQ2IO signal through the first buffers 240. Accordingly, a pulse width of the BLEQ2IO signal can be determined based on a time difference between a falling edge of the CKP1 and a rising edge of the CKP2. The BLEQ2IO signal then propagates through the second buffers 250, and is outputted as logically inverted version of the pre-charge signal, BLEQB signal. The BLEQB signal is then provided to the pre-charge circuit 118.

The pre-charge circuit 118 includes transistors, P1, P2, and P3. In some embodiments, each of the transistors P1 to P3 may be implemented as a p-type metal-oxide-semiconductor field-effect transistor. However, each of the transistors P1 to P3 may be implemented as any of various other transistors while remaining within the scope of the present disclosure. In some embodiments, the transistors P1 to P3 have their gate terminals commonly connected to an output of the last buffer 240, i.e., gated by the BLEQB signal. Respective source terminals of the transistors P1 and P2 are connected to VDD, while their respective drain terminals are connected to a bit line BL and a bit line bar BLB of the memory array 120. The bit line BL and bit line bar BLB are connected to source/drain terminals of the transistor P3. In general, when the BLEQB signal is pulled down to logic 0, the transistors P1 to P3 can be turned on, causing the transistors P1 and P2 to pull up voltage levels on the bit line BL and bit line bar BLB to VDD and causing the transistor P3 to equalize the voltage levels on the bit line BL and bit line bar BLB.

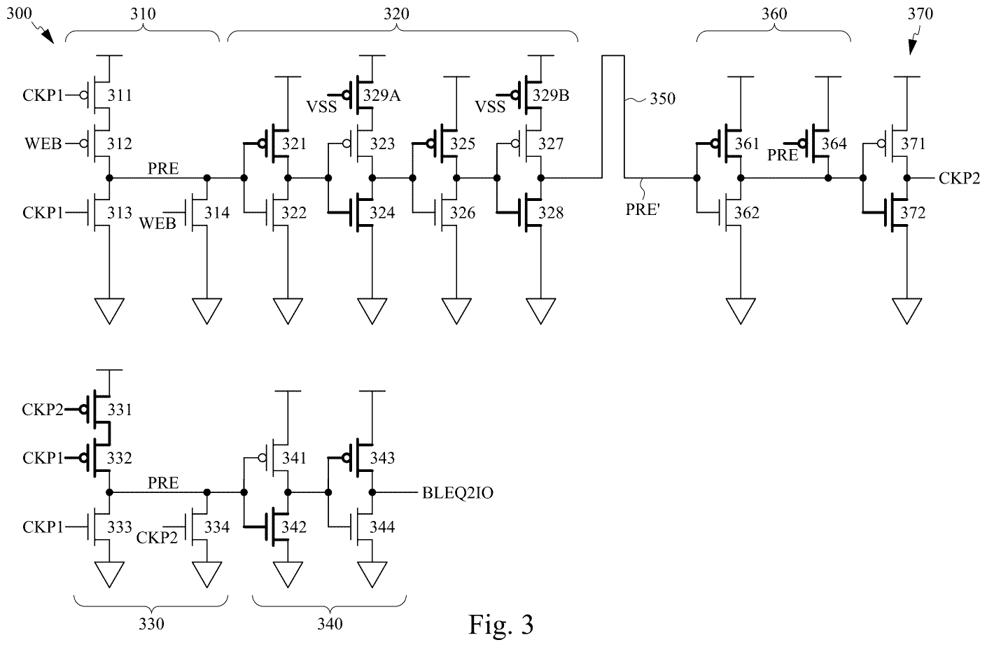

FIG. 3 illustrates a circuit diagram of one circuit implementation 300 of the timing controller 116 (FIG. 2), in accordance with some embodiments of the present disclosure. Hereinafter, the circuit implementation shown in FIG. 3 is referred to as the timing controller 300. In addition to the components illustrated in FIG. 2, the timing controller 300 includes one or more tracking metal lines configured for tracking the propagation delay of a corresponding memory array and a NAND logic gate, both of which can be incorporated into or coupled to a delay chain of the timing controller 300, which will be described as follows.

As shown, the timing controller 300 includes a first NOR gate 310, a delay chain 320, a second NOR gate 330, a group of buffers 340, which can be implementations of the first logic gate 210, the delay chain 220, the second logic gate 230, and the first buffers 240, respectively. Further, the timing controller 300 includes tracking metal lines 350, a NAND gate 360, and a last inverter stage 370 coupled to the delay chain 320. In some embodiments, the tracking metal lines 350 each physically extend along the column-wise direction of a corresponding memory array, which can be configured for tracking the propagation delay (e.g., RC delay) present on a bit line of the memory array. Stated another way, each of the tracking metal lines 350 can have a length proportional to a height of the memory array. For example, a first one of the tracking metal lines 350 may extend from an edge of the memory array and to a midpoint of the memory array, and a second one of the tracking metal lines 350 may extend from the midpoint to the edge of the memory array.

In the illustrative example of FIG. 3, the first NOR gate 310 includes transistors 311, 312, 313, and 314, in which the transistors 311 and 312 are each implemented as a p-type metal-oxide-semiconductor field-effect transistor, and the transistors 313 and 314 are each implemented as an n-type metal-oxide-semiconductor field-effect transistor. The delay chain 320 includes transistors 321, 322, 323, 324, 325, 326, 327, 328, 329A, and 329B, in which the transistors 321, 323, 325, 327, 329A, and 329B are each implemented as a p-type metal-oxide-semiconductor field-effect transistor, and the transistors 322, 324, 326, and 328 are each implemented as an n-type metal-oxide-semiconductor field-effect transistor. The NAND gate 360 includes transistors 361, 362, 363, and 364, in which the transistors 361 and 364 are each implemented as a p-type metal-oxide-semiconductor field-effect transistor, and the transistors 362 and 363 are each implemented as an n-type metal-oxide-semiconductor field-effect transistor. The last inverter stage 370 includes transistors 371 and 372, in which the transistor 371 is implemented as a p-type metal-oxide-semiconductor field-effect transistor, and the transistor 372 is implemented as an n-type metal-oxide-semiconductor field-effect transistor. The second NOR gate 330 includes transistors 331, 332, 333, and 334, in which the transistors 331 and 332 are each implemented as a p-type metal-oxide-semiconductor field-effect transistor, and the transistors 333 and 334 are each implemented as an n-type metal-oxide-semiconductor field-effect transistor. The buffers 340 include transistors 341, 342, 343, and 344, in which the transistors 341 and 343 are each implemented as a p-type metal-oxide-semiconductor field-effect transistor, and the transistors 342 and 344 are each implemented as an n-type metal-oxide-semiconductor field-effect transistor.

According to some embodiments, the transistors 311, 312, 313, and 314 of the NOR gate 310 are configured to receive CKP1, WEB signal, CKP1, and WEB signal, respectively, and are collectively to perform a NOR operation on the CKP1 and WEB signal so as to provide PRE signal. For example, during a standby mode, the WEB signal is provided at logic 1 and the CKP1 is provided at logic 0, such that the PRE signal is NOR'ed as logic 0; and during an operation mode, the WEB signal is provide at logic 0 and the CKP1 can transition between logic 0 and logic 1, such that the PRE signal is NOR'ed as transitioning to logic 1 when the CKP1 transitions to (or stays) logic 0 and NOR'ed as transitioning to logic 0 when the CKP1 transitions to (or stays at) logic 1.

The transistors 321 and 322, transistors 323 and 324, transistors 325 and 326, and transistors 327 and 328 of the delay chain 320 can operatively serve as a first one, a second one, a third one, and a fourth one of a plurality of inverter stages, respectively. The PRE signal, provided by the NOR gate 310, can propagate through the inverter stages. The first inverter stage can receive the PRE signal as its input and output its logically inverted version (PREB) as its output, the second inverter stage can receive the PREB signal as its input and output its logically inverted version (PRE) as its output, and so on. A delayed version (PRE′) of the PRE signal is outputted by the delay chain 320 (together with the tracking metal lines 350). In some embodiments, the second inverter stage (i.e., 323 and 324) further includes the transistor 329A coupled between the p-type transistor 323 and VDD, and the fourth inverter stage (i.e., 327 and 328) further includes the transistor 329B coupled between the p-type transistor 327 and VDD. Such p-type transistors 329A and 329B may be coupled to even-numbered stages of the inverters along the delay chain 320. The transistors 361, 362, 363, and 364 of the NAND gate 360 are configured to receive the PRE′ signal, PRE′s signal, PRE signal, and PRE signal, respectively, and are collectively to perform a NAND operation on the PRE′ signal and PRE signal so as to provide an input for the last inverter stage 370 that can generate the CKP2. The transistors 331, 332, 333, and 334 of the NOR gate 330 are configured to receive the CKP2, CKP1, CKP1, and CKP2, respectively, and are collectively to perform a NOR operation on the CKP1 and CKP2 so as to provide an input for the buffers 340 that can generate the BLEQ2IO signal.

In some embodiments, respective gate terminals of the transistors 329A and 329B, each of which is implemented as a p-type transistor, are tied to VSS. As such, the transistors 329A and 329B can each be configured as an always-on transistor to track the BTI effect. Stated another way, when the BTI effect becomes substantial (e.g., an increasing absolute value of the threshold voltage), the always-on transistors 329A and 329B can reflect such an adjusted threshold voltage, thereby lowering charging capability of the connected p-type transistors (e.g., 323 and 327). In some embodiments, the always-on transistors 329A and 329B may have a size (e.g., a width, a width/length ratio, etc.) smaller than the connected p-type transistor 323 and 327. Accordingly, a transition edge from those inverter stages (e.g., the second and fourth inverter stages) can be delayed, thereby intentionally delaying a transition edge of the CKP2. Thus, when the BTI effect becomes substantial, the transition (e.g., rising) edge of the CKP2 can be delayed from a transition (e.g., falling) edge of the CKP1, allowing a wider time window for pre-charging the BL/BLB.

For example, during the standby mode where the CKP1 has not yet been provided, the WEB signal and CKP1 are provided at logic 1 and logic 0, respectively, causing the PRE signal to be provided at logic 0. The first inverter stage, second inverter stage, third inverter stage, and fourth inverter stage of the delay chain 320 can output logic 1, logic 0, logic 1, and logic 0, respectively. Generally, a BTI effect may arise when the memory circuit is in the standby mode for an extended period of time. Following the standby mode, the WEB signal may be provided at logic 0 and the CKP1 is provided. Further, when the CKP1 transitions from logic 1 to logic 0, the PRE signal transitions to logic 1, which cause the first inverter stage, second inverter stage, third inverter stage, and fourth inverter stage of the delay chain 320 to pull down, pull up, pull down, and pull down their respective inputs, respectively. Since the always-on transistor 329A and 329B are connected to the second and fourth inverter stages (or pulling-up stages), the always-on transistor 329A and 329B can intentionally lower the capability of the pulling-up stages when the BTI effect is in presence. Accordingly, the rising edge of the CKP2 can be delayed. Given the delayed rising edge of the CKP2, a falling edge of the BLEQ2IO signal can be delayed, which consequently extends a pulse width of the BLEQ2IO signal.

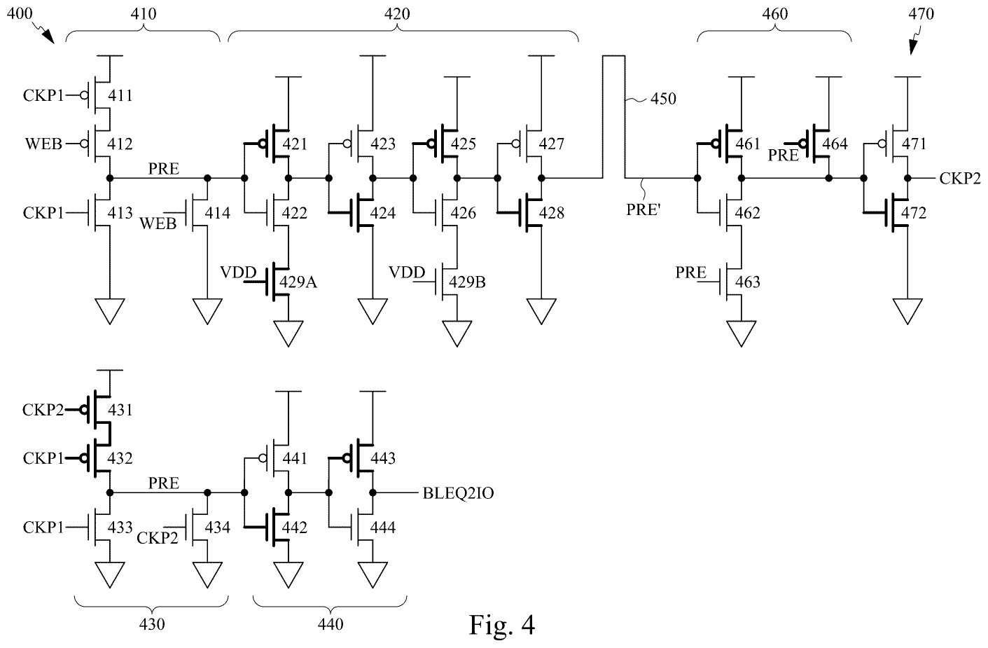

FIG. 4 illustrates a circuit diagram of another circuit implementation of the timing controller 116 (FIG. 2), in accordance with some embodiments of the present disclosure. Hereinafter, the circuit implementation shown in FIG. 4 is referred to as the timing controller 400. In addition to the components illustrated in FIG. 2, the timing controller 400 includes one or more tracking metal lines configured for tracking the propagation delay of a corresponding memory array and a NAND logic gate, both of which can be incorporated into or coupled to a delay chain of the timing controller 400, which will be described as follows.

As shown, the timing controller 400 includes a first NOR gate 410, a delay chain 420, a second NOR gate 430, a group of buffers 440, which can be implementations of the first logic gate 210, the delay chain 220, the second logic gate 230, and the first buffers 240, respectively. Further, the timing controller 400 includes tracking metal lines 450, a NAND gate 460, and a last inverter stage 470 coupled to the delay chain 420. In some embodiments, the tracking metal lines 450 each extend along the column-wise direction of a corresponding memory array, which can be configured for tracking the propagation delay (e.g., RC delay) present on a bit line of the memory array. Stated another way, each of the tracking metal lines 450 can have a length proportional to a height of the memory array. For example, a first one of the tracking metal lines 450 may extend from an edge of the memory array and to a midpoint of the memory array, and a second one of the tracking metal lines 450 may extend from the midpoint to the edge of the memory array.

In the illustrative example of FIG. 4, the first NOR gate 410 includes transistors 411, 412, 413, and 414, in which the transistors 411 and 412 are each implemented as a p-type metal-oxide-semiconductor field-effect transistor, and the transistors 413 and 414 are each implemented as an n-type metal-oxide-semiconductor field-effect transistor. The delay chain 420 includes transistors 421, 422, 423, 424, 425, 426, 427, 428, 429A, and 429B, in which the transistors 421, 423, 425, and 427 are each implemented as a p-type metal-oxide-semiconductor field-effect transistor, and the transistors 422, 424, 426, 428, 429A, and 429B are each implemented as an n-type metal-oxide-semiconductor field-effect transistor. The NAND gate 460 includes transistors 461, 462, 463, and 464, in which the transistors 461 and 464 are each implemented as a p-type metal-oxide-semiconductor field-effect transistor, and the transistors 462 and 463 are each implemented as an n-type metal-oxide-semiconductor field-effect transistor. The last inverter stage 470 includes transistors 471 and 472, in which the transistor 471 is implemented as a p-type metal-oxide-semiconductor field-effect transistor, and the transistor 472 is implemented as an n-type metal-oxide-semiconductor field-effect transistor. The second NOR gate 430 includes transistors 431, 432, 433, and 434, in which the transistors 431 and 432 are each implemented as a p-type metal-oxide-semiconductor field-effect transistor, and the transistors 433 and 434 are each implemented as an n-type metal-oxide-semiconductor field-effect transistor. The buffers 440 include transistors 441, 442, 443, and 444, in which the transistors 441 and 443 are each implemented as a p-type metal-oxide-semiconductor field-effect transistor, and the transistors 442 and 444 are each implemented as an n-type metal-oxide-semiconductor field-effect transistor.

According to some embodiments, the transistors 411, 412, 413, and 414 of the NOR gate 410 are configured to receive CKP1, WEB signal, CKP1, and WEB signal, respectively, and are collectively to perform a NOR operation on the CKP1 and WEB signal so as to provide PRE signal. For example, during a standby mode, the WEB signal is provided at logic 1 and the CKP1 is provided at logic 0, such that the PRE signal is NOR'ed as logic 0; and during an operation mode, the WEB signal is provide at logic 0 and the CKP1 can transition between logic 0 and logic 1, such that the PRE signal is NOR'ed as transitioning to logic 1 when the CKP1 transitions to (or stays) logic 0 and NOR'ed as transitioning to logic 0 when the CKP1 transitions to (or stays at) logic 1.

The transistors 421 and 422, transistors 423 and 424, transistors 425 and 426, and transistors 427 and 428 of the delay chain 420 can operatively serve as a first one, a second one, a third one, and a fourth one of a plurality of inverter stages, respectively. The PRE signal, provided by the NOR gate 410, can propagate through the inverter stages. The first inverter stage can receive the PRE signal as its input and output its logically inverted version (PREB) as its output, the second inverter stage can receive the PREB signal as its input and output its logically inverted version (PRE) as its output, and so on. A delayed version (PRE′) of the PRE signal is outputted by the delay chain 420 (together with the tracking metal lines 450). In some embodiments, the first inverter stage (i.e., 421 and 422) further includes the transistor 429A coupled between the n-type transistor 422 and VSS, and the third inverter stage (i.e., 425 and 426) further includes the transistor 429B coupled between the n-type transistor 426 and VSS. Such n-type transistors 429A and 429B may be coupled to odd-numbered stages of the inverters along the delay chain 420. The transistors 461, 462, 463, and 464 of the NAND gate 460 are configured to receive the PRE′ signal, PRE′s signal, PRE signal, and PRE signal, respectively, and are collectively to perform a NAND operation on the PRE′ signal and PRE signal so as to provide an input for the last inverter stage 470 that can generate the CKP2. The transistors 431, 432, 433, and 434 of the NOR gate 430 are configured to receive the CKP2, CKP1, CKP1, and CKP2, respectively, and are collectively to perform a NOR operation on the CKP1 and CKP2 so as to provide an input for the buffers 440 that can generate the BLEQ2IO signal.

In some embodiments, respective gate terminals of the transistors 429A and 429B, each of which is implemented as an n-type transistor, are tied to VDD. As such, the transistors 429A and 429B can each be configured as an always-on transistor to track the BTI effect. Stated another way, when the BTI effect becomes substantial (e.g., an increasing absolute value of the threshold voltage), the always-on transistors 429A and 429B can reflect such an adjusted threshold voltage, thereby lowering discharging capability of the connected n-type transistors (e.g., 422 and 426). In some embodiments, the always-on transistors 429A and 429B may have a size (e.g., a width, a width/length ratio, etc.) smaller than the connected n-type transistor 422 and 426. Accordingly, a transition edge from those inverter stages (e.g., the first and third inverter stages) can be delayed, thereby intentionally delaying a transition edge of the CKP2. Thus, when the BTI effect becomes substantial, the transition (e.g., rising) edge of the CKP2 can be delayed from a transition (e.g., falling) edge of the CKP1, allowing a wider time window for pre-charging the BL/BLB.

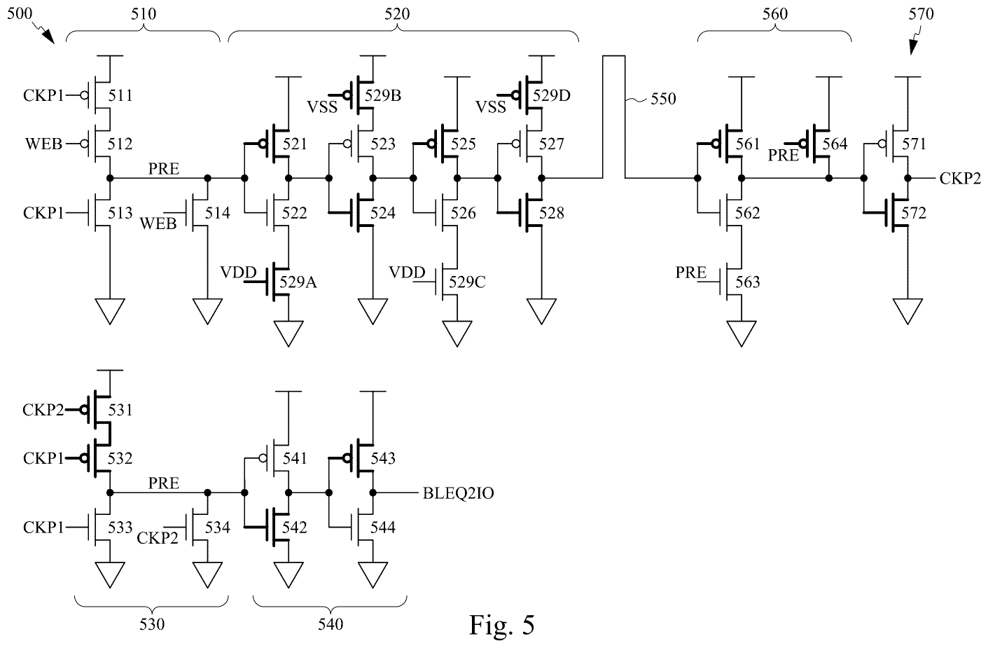

FIG. 5 illustrates a circuit diagram of yet another circuit implementation of the timing controller 116, in accordance with some embodiments of the present disclosure. Hereinafter, the circuit implementation shown in FIG. 5 is referred to as the timing controller 500. In addition to the components illustrated in FIG. 2, the timing controller 500 includes one or more tracking metal lines configured for tracking the propagation delay of a corresponding memory array and a NAND logic gate, both of which can be incorporated into or coupled to a delay chain of the timing controller 500, which will be described as follows.

As shown, the timing controller 500 includes a first NOR gate 510, a delay chain 520, a second NOR gate 530, a group of buffers 540, which can be implementations of the first logic gate 210, the delay chain 220, the second logic gate 230, and the first buffers 240, respectively. Further, the timing controller 500 includes tracking metal lines 550, a NAND gate 560, and a last inverter stage 570 coupled to the delay chain 520. In some embodiments, the tracking metal lines 550 each extend along the column-wise direction of a corresponding memory array, which can be configured for tracking the propagation delay (e.g., RC delay) present on a bit line of the memory array. Stated another way, each of the tracking metal lines 550 can have a length proportional to a height of the memory array. For example, a first one of the tracking metal lines 550 may extend from an edge of the memory array and to a midpoint of the memory array, and a second one of the tracking metal lines 550 may extend from the midpoint to the edge of the memory array.

In the illustrative example of FIG. 5, the first NOR gate 510 includes transistors 511, 512, 513, and 514, in which the transistors 511 and 512 are each implemented as a p-type metal-oxide-semiconductor field-effect transistor, and the transistors 513 and 514 are each implemented as an n-type metal-oxide-semiconductor field-effect transistor. The delay chain 520 includes transistors 521, 522, 523, 524, 525, 526, 527, 528, 529A, 529B, 529C, and 529D, in which the transistors 521, 523, 525, 527, 529B, and 529D are each implemented as a p-type metal-oxide-semiconductor field-effect transistor, and the transistors 522, 524, 526, 528, 529A, and 529C are each implemented as an n-type metal-oxide-semiconductor field-effect transistor. The NAND gate 560 includes transistors 561, 562, 563, and 564, in which the transistors 561 and 564 are each implemented as a p-type metal-oxide-semiconductor field-effect transistor, and the transistors 562 and 563 are each implemented as an n-type metal-oxide-semiconductor field-effect transistor. The last inverter stage 570 includes transistors 571 and 572, in which the transistor 571 is implemented as a p-type metal-oxide-semiconductor field-effect transistor, and the transistor 572 is implemented as an n-type metal-oxide-semiconductor field-effect transistor. The second NOR gate 530 includes transistors 531, 532, 533, and 534, in which the transistors 531 and 532 are each implemented as a p-type metal-oxide-semiconductor field-effect transistor, and the transistors 533 and 534 are each implemented as an n-type metal-oxide-semiconductor field-effect transistor. The buffers 540 include transistors 541, 542, 543, and 544, in which the transistors 541 and 543 are each implemented as a p-type metal-oxide-semiconductor field-effect transistor, and the transistors 542 and 544 are each implemented as an n-type metal-oxide-semiconductor field-effect transistor.

According to some embodiments, the transistors 511, 512, 513, and 514 of the NOR gate 510 are configured to receive CKP1, WEB signal, CKP1, and WEB signal, respectively, and are collectively to perform a NOR operation on the CKP1 and WEB signal so as to provide PRE signal. For example, during a standby mode, the WEB signal is provided at logic 1 and the CKP1 is provided at logic 0, such that the PRE signal is NOR'ed as logic 0; and during an operation mode, the WEB signal is provide at logic 0 and the CKP1 can transition between logic 0 and logic 1, such that the PRE signal is NOR'ed as transitioning to logic 1 when the CKP1 transitions to (or stays) logic 0 and NOR'ed as transitioning to logic 0 when the CKP1 transitions to (or stays at) logic 1.

The transistors 521 and 522, transistors 53 and 524, transistors 525 and 526, and transistors 527 and 528 of the delay chain 520 can operatively serve as a first one, a second one, a third one, and a fourth one of a plurality of inverter stages, respectively. The PRE signal, provided by the NOR gate 510, can propagate through the inverter stages. The first inverter stage can receive the PRE signal as its input and output its logically inverted version (PREB) as its output, the second inverter stage can receive the PREB signal as its input and output its logically inverted version (PRE) as its output, and so on. A delayed version (PRE′) of the PRE signal is outputted by the delay chain 520 (together with the tracking metal lines 550). In some embodiments, the first inverter stage (i.e., 521 and 522) further includes the transistor 529A coupled between the n-type transistor 522 and VSS, the second inverter stage (i.e., 523 and 524) further includes the transistor 529B coupled between the p-type transistor 523 and VDD, the third inverter stage (i.e., 525 and 526) further includes the transistor 529C coupled between the n-type transistor 526 and VSS, and the fourth inverter stage (i.e., 527 and 528) further includes the transistor 529D coupled between the p-type transistor 527 and VDD. Such n-type transistors 529A and 529C may be coupled to odd-numbered stages of the inverters along the delay chain 520, and the p-type transistors 529B and 529D may be coupled to even-numbered stages of the inverters along the delay chain 520. The transistors 561, 562, 563, and 564 of the NAND gate 560 are configured to receive the PRE′ signal, PRE′s signal, PRE signal, and PRE signal, respectively, and are collectively to perform a NAND operation on the PRE′ signal and PRE signal so as to provide an input for the last inverter stage 570 that can generate the CKP2. The transistors 531, 532, 533, and 534 of the NOR gate 530 are configured to receive the CKP2, CKP1, CKP1, and CKP2, respectively, and are collectively to perform a NOR operation on the CKP1 and CKP2 so as to provide an input for the buffers 540 that can generate the BLEQ2IO signal.

In some embodiments, respective gate terminals of the transistors 529A and 529C, each of which is implemented as an n-type transistor, are tied to VDD, and respective gate terminals of the transistors 529B and 529D, each of which is implemented as a p-type transistor, are tied to VSS. As such, the transistors 529A to 529D can each be configured as an always-on transistor to track the BTI effect. Stated another way, when the BTI effect becomes substantial (e.g., an increasing absolute value of the threshold voltage), the always-on transistors 529A to 529D can reflect such an adjusted threshold voltage, thereby lowering discharging capability of the connected n-type transistors and charging capability of the connected p-type transistors. In some embodiments, the always-on transistors 529A and 529C may have a size (e.g., a width, a width/length ratio, etc.) smaller than the connected n-type transistor 522 and 526. Similarly, the always-on transistors 529B and 529D may have a size (e.g., a width, a width/length ratio, etc.) smaller than the connected p-type transistor 523 and 527. Accordingly, a transition edge from those inverter stages (e.g., the first and third inverter stages) can be delayed, thereby intentionally delaying a transition edge of the CKP2. Thus, when the BTI effect becomes substantial, the transition (e.g., rising) edge of the CKP2 can be delayed from a transition (e.g., falling) edge of the CKP1, allowing a wider time window for pre-charging the BL/BLB.

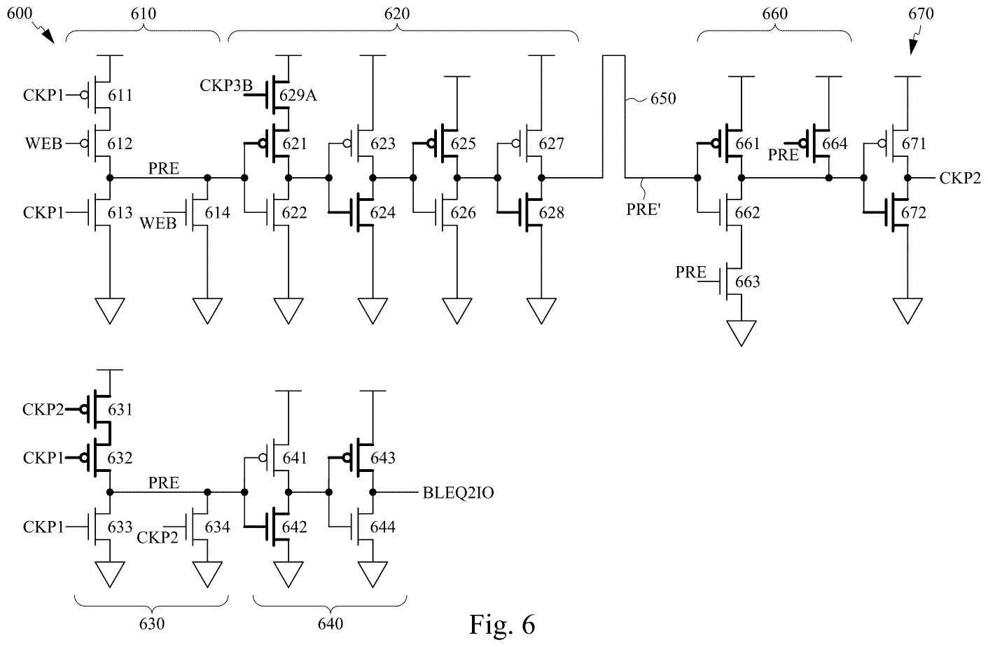

FIG. 6 illustrates a circuit diagram of yet another circuit implementation of the timing controller 116, in accordance with some embodiments of the present disclosure. Hereinafter, the circuit implementation shown in FIG. 6 is referred to as the timing controller 600. In addition to the components illustrated in FIG. 2, the timing controller 600 includes one or more tracking metal lines configured for tracking the propagation delay of a corresponding memory array and a NAND logic gate, both of which can be incorporated into or coupled to a delay chain of the timing controller 600, which will be described as follows.

As shown, the timing controller 600 includes a first NOR gate 610, a delay chain 620, a second NOR gate 630, a group of buffers 640, which can be implementations of the first logic gate 210, the delay chain 220, the second logic gate 230, and the first buffers 240, respectively. Further, the timing controller 600 includes tracking metal lines 650, a NAND gate 660, and a last inverter stage 670 coupled to the delay chain 620. In some embodiments, the tracking metal lines 650 each extend along the column-wise direction of a corresponding memory array, which can be configured for tracking the propagation delay (e.g., RC delay) present on a bit line of the memory array. Stated another way, each of the tracking metal lines 650 can have a length proportional to a height of the memory array. For example, a first one of the tracking metal lines 650 may extend from an edge of the memory array and to a midpoint of the memory array, and a second one of the tracking metal lines 650 may extend from the midpoint to the edge of the memory array.

In the illustrative example of FIG. 6, the first NOR gate 610 includes transistors 611, 612, 613, and 614, in which the transistors 611 and 612 are each implemented as a p-type metal-oxide-semiconductor field-effect transistor, and the transistors 613 and 614 are each implemented as an n-type metal-oxide-semiconductor field-effect transistor. The delay chain 620 includes transistors 621, 622, 623, 624, 625, 626, 627, 628, 629A, and 629B, in which the transistors 621, 623, 625, 627, and 629A are each implemented as a p-type metal-oxide-semiconductor field-effect transistor, and the transistors 622, 624, 626, 628, and 629B are each implemented as an n-type metal-oxide-semiconductor field-effect transistor. The NAND gate 660 includes transistors 661, 662, 663, and 664, in which the transistors 661 and 664 are each implemented as a p-type metal-oxide-semiconductor field-effect transistor, and the transistors 662 and 663 are each implemented as an n-type metal-oxide-semiconductor field-effect transistor. The last inverter stage 670 includes transistors 671 and 672, in which the transistor 671 is implemented as a p-type metal-oxide-semiconductor field-effect transistor, and the transistor 672 is implemented as an n-type metal-oxide-semiconductor field-effect transistor. The second NOR gate 630 includes transistors 631, 632, 633, and 634, in which the transistors 631 and 632 are each implemented as a p-type metal-oxide-semiconductor field-effect transistor, and the transistors 633 and 634 are each implemented as an n-type metal-oxide-semiconductor field-effect transistor. The buffers 640 include transistors 641, 642, 643, and 644, in which the transistors 641 and 643 are each implemented as a p-type metal-oxide-semiconductor field-effect transistor, and the transistors 642 and 644 are each implemented as an n-type metal-oxide-semiconductor field-effect transistor.

According to some embodiments, the transistors 611, 612, 613, and 614 of the NOR gate 610 are configured to receive CKP1, WEB signal, CKP1, and WEB signal, respectively, and are collectively to perform a NOR operation on the CKP1 and WEB signal so as to provide PRE signal. For example, during a standby mode, the WEB signal is provided at logic 1 and the CKP1 is provided at logic 0, such that the PRE signal is NOR'ed as logic 0; and during an operation mode, the WEB signal is provide at logic 0 and the CKP1 can transition between logic 0 and logic 1, such that the PRE signal is NOR'ed as transitioning to logic 1 when the CKP1 transitions to (or stays) logic 0 and NOR'ed as transitioning to logic 0 when the CKP1 transitions to (or stays at) logic 1.

The transistors 621 and 622, transistors 623 and 624, transistors 625 and 626, and transistors 627 and 628 of the delay chain 620 can operatively serve as a first one, a second one, a third one, and a fourth one of a plurality of inverter stages, respectively. The PRE signal, provided by the NOR gate 610, can propagate through the inverter stages. The first inverter stage can receive the PRE signal as its input and output its logically inverted version (PREB) as its output, the second inverter stage can receive the PREB signal as its input and output its logically inverted version (PRE) as its output, and so on. A delayed version (PRE′) of the PRE signal is outputted by the delay chain 620 (together with the tracking metal lines 650). In some embodiments, the first inverter stage (i.e., 621 and 622) further includes the transistor 629A coupled between the p-type transistor 623 and VDD, and the transistor 629B is coupled between an output of the first inverter stage and an input of the second inverter stage (i.e., 623 and 624). Respective gate terminals of the transistor 629A and the transistor 629B are coupled to a control signal (CKP3B). The CKP3B signal may be provided at logic 1 and at logic 0 when in the standby mode and operation mode, respectively. The transistors 661, 662, 663, and 664 of the NAND gate 660 are configured to receive the PRE′ signal, PRE′s signal, PRE signal, and PRE signal, respectively, and are collectively to perform a NAND operation on the PRE′ signal and PRE signal so as to provide an input for the last inverter stage 670 that can generate the CKP2. The transistors 631, 632, 633, and 634 of the NOR gate 630 are configured to receive the CKP2, CKP1, CKP1, and CKP2, respectively, and are collectively to perform a NOR operation on the CKP1 and CKP2 so as to provide an input for the buffers 640 that can generate the BLEQ2IO signal.

In some embodiments, respective gate terminals of the transistors 629A and 629B, which are implemented as a p-type transistor and an n-type transistor, respectively, are configured to receive the same CKP3B signal. Further, when in the standby mode, the CKP3B signal is provided at logic 1; and when in the operation mode, the CKP3B signal is provided at logic 0. As such, the transistors 629A and 629B can be turned off and on, respectively, when in the standby mode, and the transistors 629A and 629B can be turned on and off, respectively, when in the operation mode, so as to track the BTI effect. Stated another way, when the BTI effect becomes substantial (e.g., an increasing absolute value of the threshold voltage), in the standby mode, the turned-off transistor 629A and the turned-on transistor 629B can change a polarity of the output of the first inverter stage, and a polarity of each of the following inverter stages. Accordingly, the transistors 623, 626, and 627 can reflect the adjusted threshold voltage. When switching into the operation mode (in which the transistor 629A is turned on and the transistor 629B is turned off), the transistors 623, 626, and 627 can be configured to track the BTI effect. Accordingly, a transition edge from each of the inverter stages can be delayed, thereby intentionally delaying a transition edge of the CKP2. Thus, when the BTI effect becomes substantial, the transition (e.g., rising) edge of the CKP2 can be delayed from a transition (e.g., falling) edge of the CKP1, allowing a wider time window for pre-charging the BL/BLB.

For example, during the standby mode where the CKP1 has not yet been provided, the WEB signal and CKP1 are provided at logic 1 and logic 0, respectively, causing the PRE signal to be provided at logic 0. By turning off the transistor 629A and turning on the transistor 629B (by the CKP3B signal), the first inverter stage, second inverter stage, third inverter stage, and fourth inverter stage of the delay chain 620 can output logic 0, logic 1, logic 0, and logic 1, respectively. If there is a BTI effect in presence, the turned-off transistor 629A and the turned-on transistor 629B can track threshold voltage degradation of the transistors 621, 623, 626, and 627 caused by the BTI effect. Following the standby mode, the WEB signal may be provided at logic 0 and the CKP1 is provided. Further, when the CKP1 transitions from logic 1 to logic 0, the PRE signal transitions to logic 1, which cause the first inverter stage, second inverter stage, third inverter stage, and fourth inverter stage of the delay chain 620 to pull down, pull up, pull down, and pull down their respective inputs, respectively. Since the transistor 623, 626, and 627 reflects the adjusted threshold voltage, the pulling-up capability of the second inverter stage, the pulling-down capability of the third inverter stage, and the pulling-up capability of the fourth inverter stage can be lower when the BTI effect is in presence. Accordingly, the rising edge of the CKP2 can be delayed. Given the delayed rising edge of the CKP2, a falling edge of the BLEQ2IO signal can be delayed, which consequently extends a pulse width of the BLEQ2IO signal.

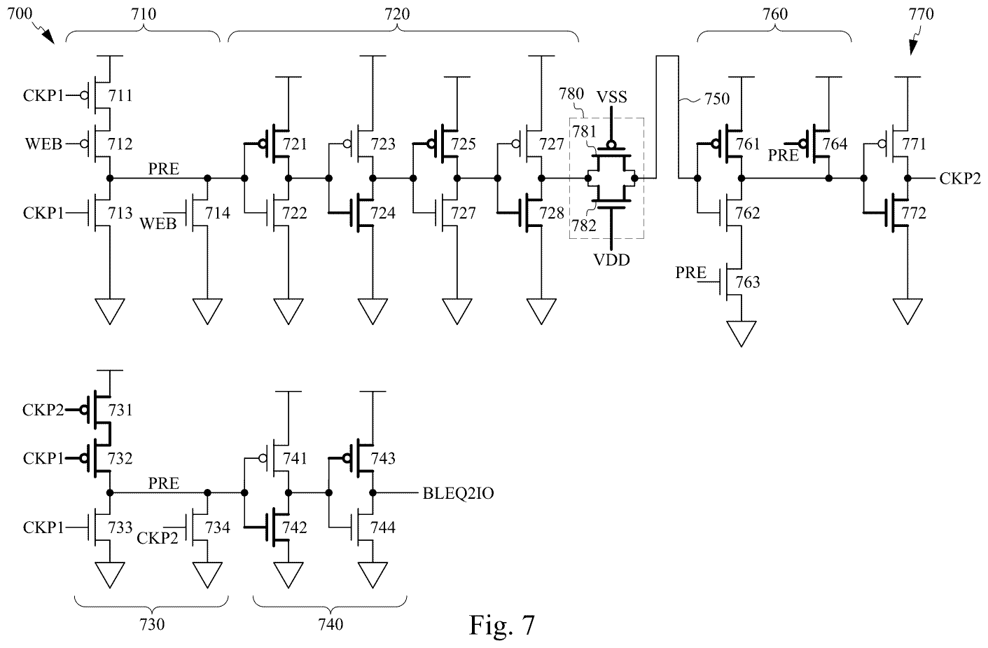

FIG. 7 illustrates a circuit diagram of yet another circuit implementation of the timing controller 116, in accordance with some embodiments of the present disclosure. Hereinafter, the circuit implementation shown in FIG. 7 is referred to as the timing controller 700. In addition to the components illustrated in FIG. 2, the timing controller 700 includes one or more tracking metal lines configured for tracking the propagation delay of a corresponding memory array and a NAND logic gate, both of which can be incorporated into or coupled to a delay chain of the timing controller 700, which will be described as follows.

As shown, the timing controller 700 includes a first NOR gate 710, a delay chain 720, a second NOR gate 730, a group of buffers 740, which can be implementations of the first logic gate 210, the delay chain 220, the second logic gate 230, and the first buffers 240, respectively. Further, the timing controller 700 includes tracking metal lines 750, a NAND gate 760, a last inverter stage 770, and a transmission gate 780 coupled to the delay chain 720. In some embodiments, the tracking metal lines 750 each extend along the column-wise direction of a corresponding memory array, which can be configured for tracking the propagation delay (e.g., RC delay) present on a bit line of the memory array. Stated another way, each of the tracking metal lines 750 can have a length proportional to a height of the memory array. For example, a first one of the tracking metal lines 750 may extend from an edge of the memory array and to a midpoint of the memory array, and a second one of the tracking metal lines 750 may extend from the midpoint to the edge of the memory array.

In the illustrative example of FIG. 7, the first NOR gate 710 includes transistors 711, 712, 713, and 714, in which the transistors 711 and 712 are each implemented as a p-type metal-oxide-semiconductor field-effect transistor, and the transistors 713 and 714 are each implemented as an n-type metal-oxide-semiconductor field-effect transistor. The delay chain 720 includes transistors 721, 722, 723, 724, 725, 726, 727, and 728, in which the transistors 721, 723, 725, and 727 are each implemented as a p-type metal-oxide-semiconductor field-effect transistor, and the transistors 722, 724, 726, and 728 are each implemented as an n-type metal-oxide-semiconductor field-effect transistor. The NAND gate 760 includes transistors 761, 762, 763, and 764, in which the transistors 761 and 764 are each implemented as a p-type metal-oxide-semiconductor field-effect transistor, and the transistors 762 and 763 are each implemented as an n-type metal-oxide-semiconductor field-effect transistor. The last inverter stage 770 includes transistors 771 and 772, in which the transistor 771 is implemented as a p-type metal-oxide-semiconductor field-effect transistor, and the transistor 772 is implemented as an n-type metal-oxide-semiconductor field-effect transistor. The second NOR gate 730 includes transistors 731, 732, 733, and 734, in which the transistors 731 and 732 are each implemented as a p-type metal-oxide-semiconductor field-effect transistor, and the transistors 733 and 734 are each implemented as an n-type metal-oxide-semiconductor field-effect transistor. The buffers 740 include transistors 741, 742, 743, and 744, in which the transistors 741 and 743 are each implemented as a p-type metal-oxide-semiconductor field-effect transistor, and the transistors 742 and 744 are each implemented as an n-type metal-oxide-semiconductor field-effect transistor. The transmission gate 780 includes transistors 781 and 782, in which the transistor 781 is implemented as a p-type metal-oxide-semiconductor field-effect transistor, and the transistor 782 is implemented as an n-type metal-oxide-semiconductor field-effect transistor.

According to some embodiments, the transistors 711, 712, 713, and 714 of the NOR gate 710 are configured to receive CKP1, WEB signal, CKP1, and WEB signal, respectively, and are collectively to perform a NOR operation on the CKP1 and WEB signal so as to provide PRE signal. For example, during a standby mode, the WEB signal is provided at logic 1 and the CKP1 is provided at logic 0, such that the PRE signal is NOR'ed as logic 0; and during an operation mode, the WEB signal is provide at logic 0 and the CKP1 can transition between logic 0 and logic 1, such that the PRE signal is NOR'ed as transitioning to logic 1 when the CKP1 transitions to (or stays) logic 0 and NOR'ed as transitioning to logic 0 when the CKP1 transitions to (or stays at) logic 1.

The transistors 721 and 722, transistors 723 and 724, transistors 725 and 726, and transistors 727 and 728 of the delay chain 720 can operatively serve as a first one, a second one, a third one, and a fourth one of a plurality of inverter stages, respectively. The PRE signal, provided by the NOR gate 710, can propagate through the inverter stages. The first inverter stage can receive the PRE signal as its input and output its logically inverted version (PREB) as its output, the second inverter stage can receive the PREB signal as its input and output its logically inverted version (PRE) as its output, and so on. A delayed version (PRE′) of the PRE signal is outputted by the delay chain 720 (together with the transmission gate 780 and tracking metal lines 750). In some embodiments, a gate terminal of the p-type transistor 781 of the transmission gate 780 is tied to VSS, and a gate terminal of the n-type transistor 782 of the transmission gate 780 is tied to VDD. The transistors 761, 762, 763, and 764 of the NAND gate 760 are configured to receive the PRE′ signal, PRE′s signal, PRE signal, and PRE signal, respectively, and are collectively to perform a NAND operation on the PRE′ signal and PRE signal so as to provide an input for the last inverter stage 770 that can generate the CKP2. The transistors 731, 732, 733, and 734 of the NOR gate 730 are configured to receive the CKP2, CKP1, CKP1, and CKP2, respectively, and are collectively to perform a NOR operation on the CKP1 and CKP2 so as to provide an input for the buffers 740 that can generate the BLEQ2IO signal.

In some embodiments, respective gate terminals of the transistors 781 and 782 (of the transmission gate 780), which are implemented as a p-type transistor and n-type transistor, are tied to VSS and VDD, respectively. As such, the transmission gate 780 can be configured as an always-on transmission gate to track the BTI effect. Stated another way, when the BTI effect becomes substantial (e.g., an increasing absolute value of the threshold voltage), the always-on t transmission gate 780 can reflect such an adjusted threshold voltage, thereby intentionally delaying a transition edge of the CKP2. Thus, when the BTI effect becomes substantial, the transition (e.g., rising) edge of the CKP2 can be delayed from a transition (e.g., falling) edge of the CKP1, allowing a wider time window for pre-charging the BL/BLB.

For example, during the standby mode where the CKP1 has not yet been provided, the WEB signal and CKP1 are provided at logic 1 and logic 0, respectively, causing the PRE signal to be provided at logic 0. The first inverter stage, second inverter stage, third inverter stage, and fourth inverter stage of the delay chain 720 can output logic 1, logic 0, logic 1, and logic 0, respectively. If there is a BTI effect in presence, the always-on transmission gate 780 can track threshold voltage degradation caused by the BTI effect. Following the standby mode, the WEB signal may be provided at logic 0 and the CKP1 is provided. Further, when the CKP1 transitions from logic 1 to logic 0, the PRE signal transitions to logic 1, which cause the first inverter stage, second inverter stage, third inverter stage, and fourth inverter stage of the delay chain 720 to pull down, pull up, pull down, and pull down their respective inputs, respectively. Since the transmission gate 780 is always turned on, an equivalent resistance of the transmission gate 780 can increase in accordance with an age of the whole circuit to track the BTI effect. Accordingly, the rising edge of the CKP2 can be delayed. Given the delayed rising edge of the CKP2, a falling edge of the BLEQ2IO signal can be delayed, which consequently extends a pulse width of the BLEQ2IO signal.

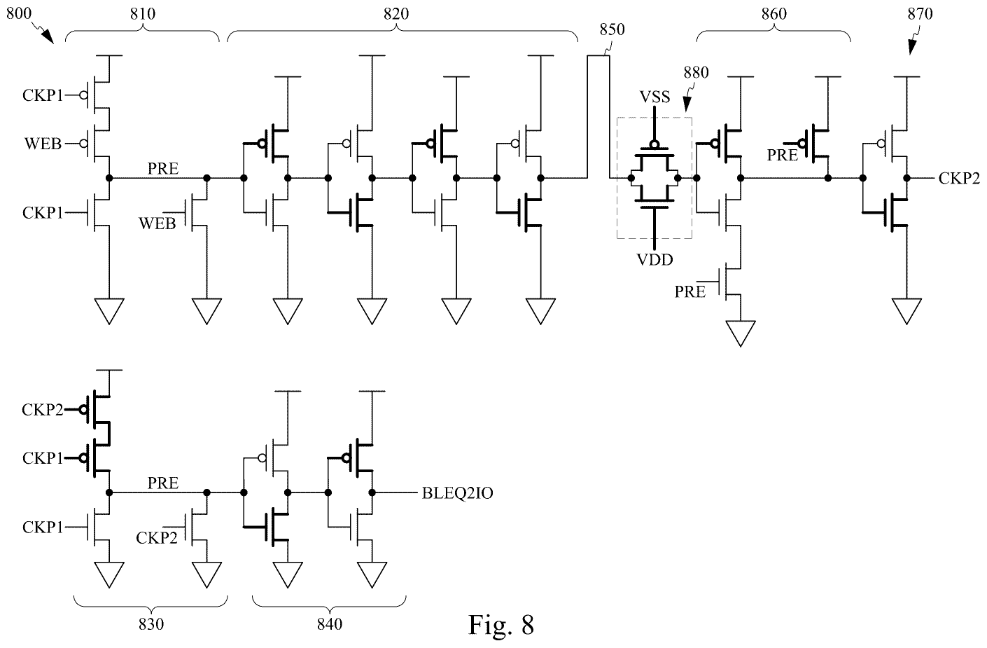

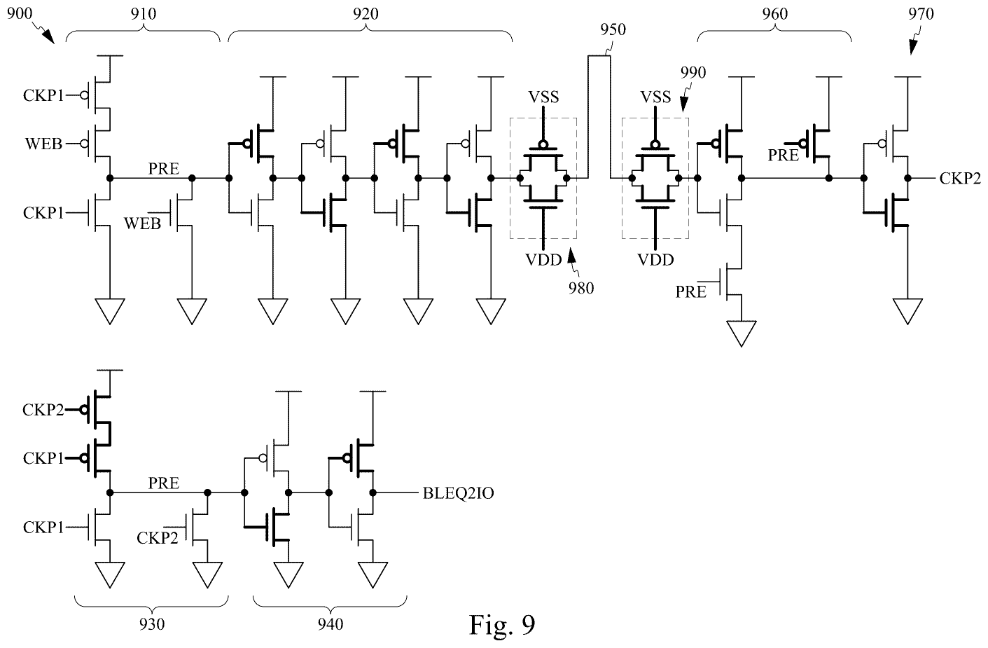

FIG. 8 and FIG. 9 each illustrate a circuit diagram of yet another circuit implementation of the timing controller 116, in accordance with some embodiments of the present disclosure. Hereinafter, the circuit implementations shown in FIGS. 8 and 9 are referred to as the timing controller 800 and timing controller 900, respectively. The timing controllers 800 and 900 are each similar to the timing controller 700 except a location of the always-on transmission gate or a number of the always-on transmission gates, and thus, the following discussion of the timing controllers 800 and 900 will be focused on the difference.

In the illustrative example of FIG. 8, the timing controller 800 includes a first NOR gate 810, a delay chain 820, tracking metal lines 850, a transmission gate 880, a NAND gate 860, a last inverter stage 870, a second NOR gate 830, and a group of buffers 840. The transmission gate 880 also includes one always-on p-type transistor and one always-on n-type transistor. Different from the timing controller 700, the transmission gate 880 of the timing controller 800 is coupled between the tracking metal lines 850 and the NAND gate 860.

In the illustrative example of FIG. 9, the timing controller 900 includes a first NOR gate 910, a delay chain 920, a first transmission gate 980, tracking metal lines 950, a second transmission gate 990, a NAND gate 960, a last inverter stage 970, a second NOR gate 930, and a group of buffers 940. Each of the transmission gates 980 and 990 also includes one always-on p-type transistor and one always-on n-type transistor. Different from the timing controller 700, the transmission gate 980 and the transmission gate 990 of the timing controller 900 is coupled to two ends of the tracking metal lines 950. Stated another way, the transmission gate 980 is coupled between an output of the fourth inverter stage of the delay chain 920 and the tracking metal lines 950; and the transmission gate 990 is coupled between the tracking metal lines 950 the NAND gate 960.

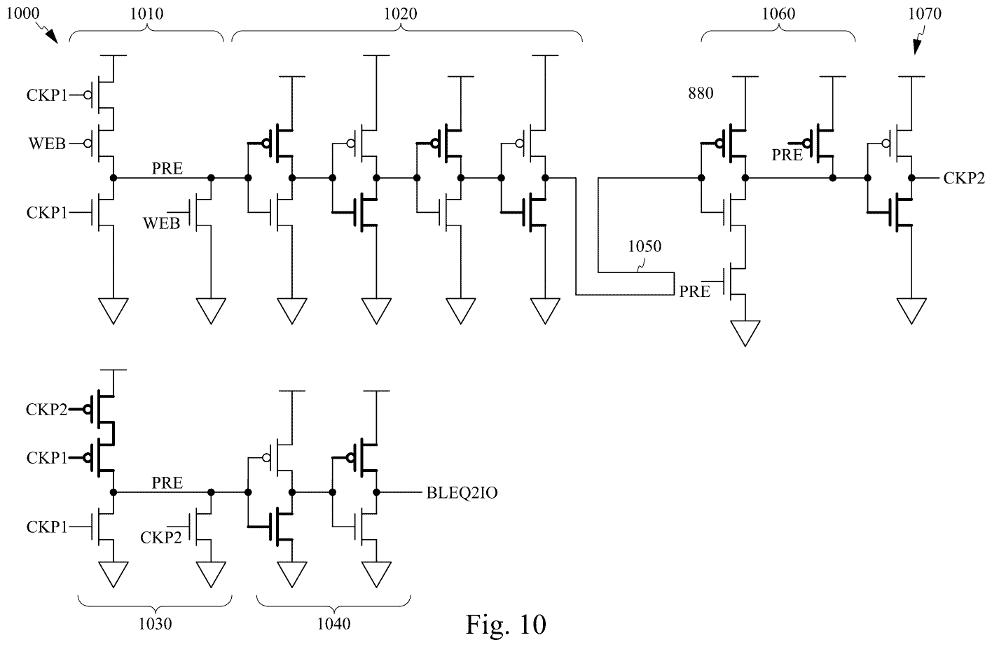

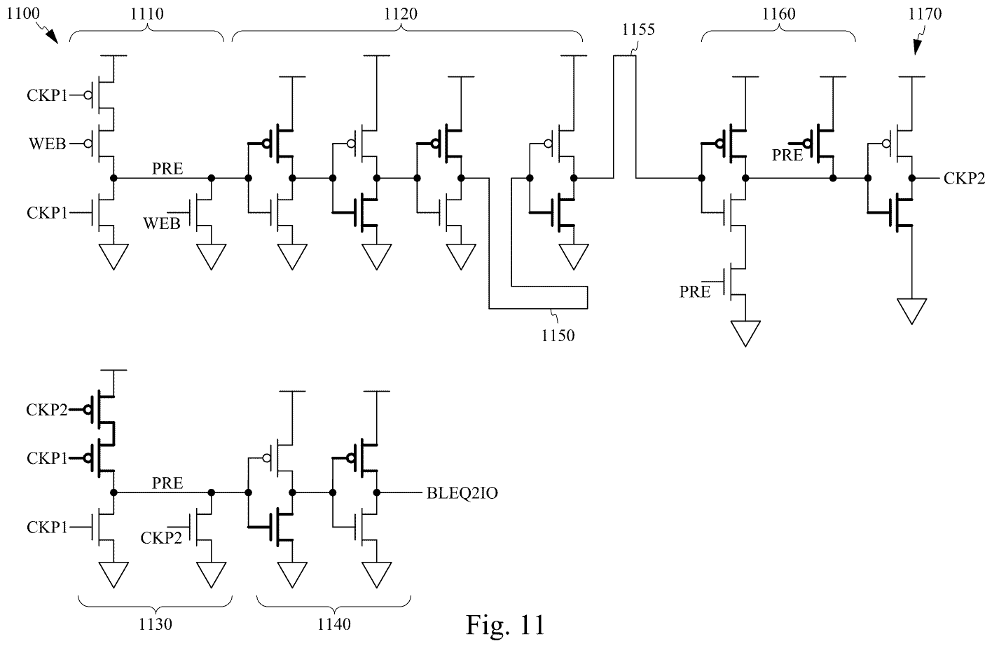

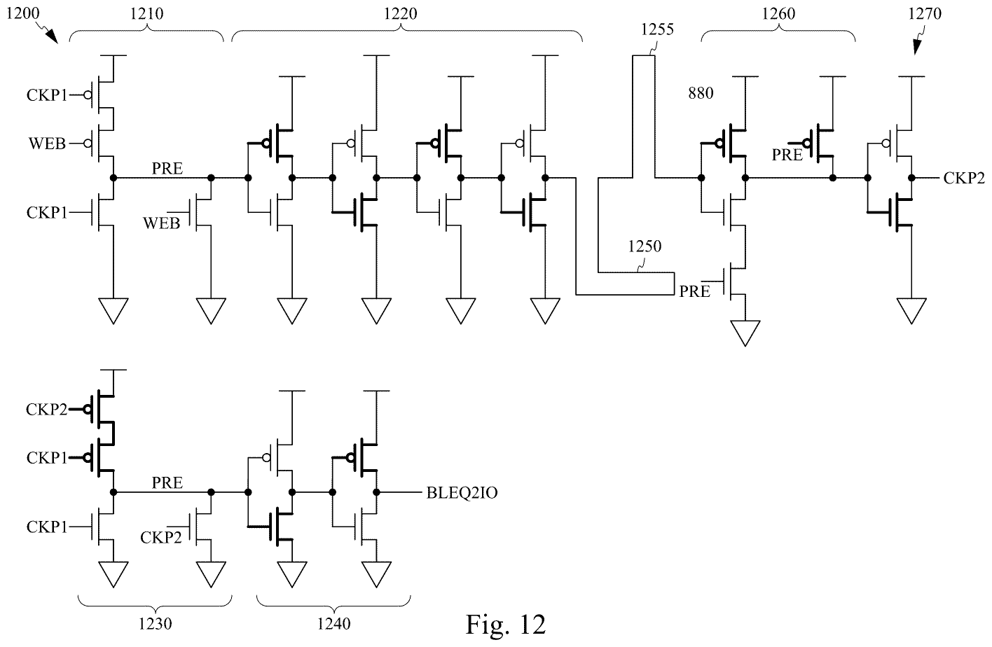

FIG. 10, FIG. 11, and FIG. 12 each illustrate a circuit diagram of yet another circuit implementation of the timing controller 116, in accordance with some embodiments of the present disclosure. Hereinafter, the circuit implementations shown in FIGS. 10, 11, and 12 are referred to as the timing controller 1000, timing controller 1100, and timing controller 1200, respectively. The timing controllers 1000 to 1200 are each similar to the timing controller 300 except a configuration of the tracking metal lines or a number of the tracking metal lines, and thus, the following discussion of the timing controllers 1000 to 1200 will be focused on the difference.

In the illustrative example of FIG. 10, the timing controller 1000 includes a first NOR gate 1010, a delay chain 1020, tracking metal lines 1050, a NAND gate 1060, a last inverter stage 1070, a second NOR gate 1030, and a group of buffers 1040. The tracking metal lines 1050 are also coupled between the delay chain 1020 and the NAND gate 1060. Different from the timing controller 300, the tracking metal lines 1050 of the timing controller 1000 each physically extend along the row-wise direction of a corresponding memory array, which can be configured for tracking the propagation delay (e.g., RC delay) present on a word line of the memory array. Stated another way, each of the tracking metal lines 1050 can have a length proportional to a width of the memory array. For example, a first one of the tracking metal lines 1050 may extend from an edge of the memory array and to a midpoint of the memory array, and a second one of the tracking metal lines 1050 may extend from the midpoint to the edge of the memory array.

In the illustrative example of FIG. 11, the timing controller 1100 includes a first NOR gate 1110, a delay chain 1120, first tracking metal lines 1150, second tracking metal lines 1155, a NAND gate 1160, a last inverter stage 1170, a second NOR gate 1130, and a group of buffers 1140. In some embodiments, the first tracking metal lines 1150 are coupled between the adjacent inverter stages of the delay chain 1120, and the second tracking metal lines 1155 are coupled between the delay chain 1120 and the NAND gate 1160. Further, the first tracking metal lines 1150 each physically extend along the row-wise direction of a corresponding memory array, while the second tracking metal lines 1155 each physically extend along the column-wise direction of the memory array. Stated another way, each of the first tracking metal lines 1150 can have a length proportional to a width of the memory array, and each of the second tracking metal lines 1155 can have a length proportional to a height of the memory array. For example, a first one of the first tracking metal lines 1150 may extend from a first edge of the memory array and to a midpoint of the memory array, and a second one of the first tracking metal lines 1150 may extend from the midpoint to the first edge of the memory array; and a first one of the second tracking metal lines 1155 may extend from a second edge of the memory array and to the midpoint of the memory array, and a second one of the second tracking metal lines 1155 may extend from the midpoint to the second edge of the memory array. In some embodiments, the first edge may be perpendicular to the second edge.

In the illustrative example of FIG. 12, the timing controller 1200 includes a first NOR gate 1210, a delay chain 1220, first tracking metal lines 1250, second tracking metal lines 1255, a NAND gate 1260, a last inverter stage 1270, a second NOR gate 1230, and a group of buffers 1240. In some embodiments, the first tracking metal lines 1250 and the second tracking metal lines 1255 are coupled between the delay chain 1220 and the NAND gate 1260. Further, the first tracking metal lines 1250 each physically extend along the row-wise direction of a corresponding memory array, while the second tracking metal lines 1255 each physically extend along the column-wise direction of the memory array. Stated another way, each of the first tracking metal lines 1250 can have a length proportional to a width of the memory array, and the each of the second tracking metal lines 1255 can have a length proportional to a height of the memory array. For example, a first one of the first tracking metal lines 1250 may extend from a first edge of the memory array and to a midpoint of the memory array, and a second one of the first tracking metal lines 1250 may extend from the midpoint to the first edge of the memory array; and a first one of the second tracking metal lines 1255 may extend from a second edge of the memory array and to the midpoint of the memory array, and a second one of the second tracking metal lines 1255 may extend from the midpoint to the second edge of the memory array. In some embodiments, the first edge may be perpendicular to the second edge.

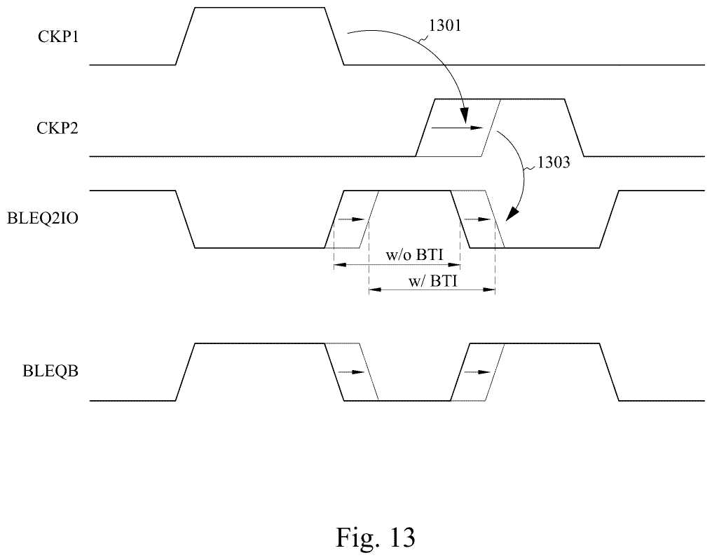

FIG. 13 illustrates example waveforms of various signals that change over time when operating the timing controller 116 operatively coupled to the memory array 120, in accordance with various embodiments of the present disclosure. For example, the CKP1, CKP2, BLEQ2IO signal, and BLEQB signal are shown, when operating the timing controller 116. It should be understood the waveforms of the signals shown in FIG. 13 are provided merely for illustrative purposes. Thus, configurations of those signals (e.g., scales) can be changed while remaining within the scope of the present disclosure.

As shown, the CKP1 and the CKP2 have respective pulses. The CKP1 may be generated in response to a clock signal (e.g., being pulled up), and the CKP2 may be generated right after the CKP1 (e.g., being pulled down). In some examples, the pulses of the CKP1 and CKP2 may reside within one half of the cycle of the clock signal. The pulses of the CKP2 immediately follows the pulse of the pulse of the CKP1, i.e., the CKP1 held at logic 0 after being pulled down and the CKP2 held at logic 1 until being pulled up. In one aspect, the pulse of the CKP1 may be configured for a read operation of the memory array 120, and the pulse of the CKP2 may be configured for a write operation of the memory array 120. In another aspect, the pulse of the CKP1 may be configured for a write operation of the memory array 120, and the pulse of the CKP2 may be configured for a read operation of the memory array 120.

With any of the implementations shown in FIGS. 3 to 12, a rising edge of the CKP2 (or its pulse) can be delayed from a falling edge of the CKP1 (or its pulse), as indicated by symbolic arrow 1301. Such an intentional delay can advantageously help widen a pulse window of the BLEQ2IO signal, a logically inverted version of which is the BLEQB signal configured for activating a corresponding pre-charge circuit (e.g., 118). As discussed above, the BLEQ2IO signal is generated by NOR'ing the CKP1 and CKP2, and thus, the pulse window of the BLEQ2IO signal is determined based on a time difference between the falling edge of the CKP1 and the rising edge of the CKP2. When a BTI effect is in presence, the pulse window of the BLEQ2IO signal may be squeezed, e.g., with a delayed rising edge. To compensate for this effect, the delayed rising edge of the CKP2 can help delay a falling edge of the BLEQ2IO signal, as indicated by symbolic arrow 1303. As a result, even with the BTI effect, the squeezed pulse window of the BLEQ2IO signal can be restored.

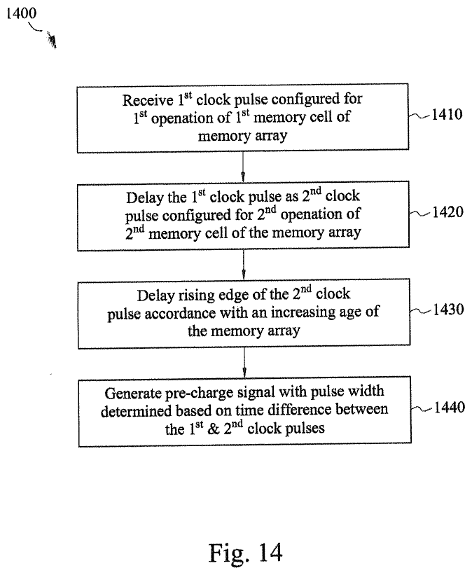

FIG. 14 illustrates a flow chart of an example method 1400 for operating a memory circuit, in accordance with various embodiments of the present disclosure. The operations of the method 1400 may be performed by the components described above (e.g., FIGS. 1-13), and thus, some of the reference numerals used above may be re-used the following discussion of the method 1400. For example, the method 1400 can be performed by a timing controller to track BTI effect so as to optimize the pulse window of a pre-charge signal. Further, it should be understood that the method 1400 has been simplified, and thus, additional operations may be provided before, during, and after the method 1400 of FIG. 14, and that some other operations may only be briefly described herein.

The method 1400 starts with operation 1410 of receiving a first clock pulse configured for a first operation of a first memory cell within a memory array. In some embodiments, the memory array can include a number of memory cells, each of which may be configured as a double-pumped SRAM cell. For example, any of the memory cells can be sequentially read then written within one cycle of a clock signal. In some embodiments, the first clock pulse may be generated in response to a rising edge of the clock signal. Using the memory circuit 100 of FIG. 1 as a non-limiting example, the timing controller 116 can receive a clock signal and generate the first clock pulse (e.g., CKP1) in response to the clock signal being pulled up.

The method 1400 continues to operation 1420 of delaying the first clock pulse as a second clock pulse configured for a second operation of a second memory cell within the memory array. As a non-limiting example, a first one of the memory cells can be first selected to be read according to the first clock pulse (CKP1), and a second one of the memory cells can be then selected to be written according to the second clock pulse (e.g., CKP2). In some embodiments, the first memory cell and the second memory cell are different memory cells that can be arranged on the same word line WL or on respective word lines WLs. In some other embodiments, the first memory cell and the second memory cell can be the same memory cell. The first clock pulse and the second clock pulse that immediately follows the first clock pulse are within one clock cycle. Continuing with the above example, the timing controller 116 can generate the second clock pulse (CKP2) right after the first clock pulse (CKP1). Further, the timing controller 116 can include a delay chain configured to delay the first clock pulse as the second clock pulse, in accordance with various embodiments.

The method 1400 continues to operation 1430 of delaying a rising edge of the second clock pulse in accordance with an increasing age of the memory array. Continuing with the above example, the timing controller 116 can include a plural number of transistors coupled with the delay chain, which allows the rising edge of the second clock pulse to be delayed when a BTI effect is in presence, in accordance with various embodiments. In one aspect, the transistors can include always-on p-type transistors coupling VDD to even-numbered inverter stages of the delay chain, respectively. In another aspect, the transistors can include always-on n-type transistors coupling VSS to odd-numbered inverter stages of the delay chain, respectively. In yet another aspect, the transistors can include a pair of transistors gated by a control signal to alter the polarity of an output of each of the inverter stages except for the first inverter stage. In yet another aspect, the transistors can include one or more always-on transmission gates.

The method 1400 continues to operation 1440 of generating a pre-charge signal with a pulse width determined based on a time difference between the first clock pulse and the second clock pulse. Still with the above example, the timing controller 116 can generate the pre-charge signal (e.g., BLEQ2IO signal or its logically inverted version, BLEQB signal) by NOR'ing the first clock pulse (CKP1) and the second clock pulse (CKP2). In some embodiments, the pulse width of the BLEQ2IO signal is determined based on a time difference between a falling edge of the CKP1 and a rising edge of the CKP2. When the BTI effect is in presence, the timing controller 116 can track the effect to delay the rising edge of the CKP2, so as to widen or maintain the pulse width of the BLEQ2IO. Consequently, a corresponding pre-charge circuit (e.g., 118) can have ample time to pre-charge bit lines to the correct voltage level.

In one aspect of the present disclosure, a memory circuit is disclosed. The memory circuit includes a memory array including a plurality of memory cells, wherein each of the plurality of memory cells is accessible through a plurality of access lines. The memory circuit includes a delay circuit configured to receive a first clock pulse and delay the first clock pulse as a second clock pulse, wherein the second clock pulse immediately follows the first clock pulse. The memory circuit includes a logic gate configured to receive the first clock pulse and the second clock pulse, and provide a pre-charge signal for pre-charging the plurality of access lines based on the first and second clock pulses. The delay circuit includes a plurality of inverters and a plurality of transistors, such that a time difference between a first transition edge of the first clock pulse and a second transition edge of the second clock pulse is extended in accordance with an increasing age of the memory circuit.

In another aspect of the present disclosure, a memory circuit is disclosed. The memory circuit includes a delay circuit configured to receive a first clock pulse and delay the first clock pulse as a second clock pulse, wherein the first clock pulse and the second clock pulse are within one clock cycle. The delay circuit includes a plurality of inverters and a plurality of transistors, and the plurality of transistors are configured such as to delay a rising edge of the second clock pulse that follows a falling edge of the first clock pulse in accordance with an increasing age of the memory circuit.

In yet another aspect of the present disclosure, a method for operating a memory circuit is disclosed. The method includes receiving a first clock pulse configured for a first operation of a first memory cell within a memory array. The method includes delaying the first clock pulse as a second clock pulse configured for a second operation of a second memory cell within the memory array, wherein the first clock pulse and the second clock pulse, that immediately follows a falling edge of the first clock pulse, are within one clock cycle. The method includes pre-charging a first bit line coupled to the first memory cell and a second bit line coupled to the second memory cell. The method includes delaying a rising edge of the second clock pulse.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory circuit, comprising:
a memory array including a plurality of memory cells, wherein each of the plurality of memory cells is accessible through a plurality of access lines;
a delay circuit configured to receive a first clock pulse and delay the first clock pulse as a second clock pulse, wherein the second clock pulse immediately follows the first clock pulse;
a logic gate configured to receive the first clock pulse and the second clock pulse, and provide a pre-charge signal for pre-charging the plurality of access lines based on the first and second clock pulses;
wherein the delay circuit includes a plurality of inverters and a plurality of transistors, such that a time difference between a first transition edge of the first clock pulse and a second transition edge of the second clock pulse is extended in accordance with an increasing age of the memory circuit.

2. The memory circuit of claim 1, wherein the first clock pulse and the second clock pulse are within one clock cycle.

3. The memory circuit of claim 1, wherein the first transition edge is a falling edge and the second transition edge is a rising edge.

4. The memory circuit of claim 1, wherein at least a first one of the memory cells is configured to be read during the first clock pulse, at least a second one of the memory cells is configured to be programmed, and the access lines of the memory cells are configured to be pre-charged to a logic state between the first clock pulse and the second clock pulse.

5. The memory circuit of claim 1, wherein the plurality of transistors include p-type transistors connected to even-numbered stages of the plurality of inverters, and wherein respective gate terminals of the p-type transistors are connected to VSS.

6. The memory circuit of claim 1, wherein the plurality of transistors include p-type transistors connected to even-numbered stages of the plurality of inverters and n-type transistors connected to odd-numbered stages of the plurality of inverters, and wherein respective gate terminals of the p-type transistors are connected to VSS and respective gate terminals of the n-type transistors are connected to VDD.

7. The memory circuit of claim 1, wherein the plurality of transistors include a p-type transistor connected to a first stage of the plurality of inverters and an n-type transistor connected to an input of a second stage of the plurality of inverters, and wherein respective gate terminals of the p-type transistor and the n-type transistor are both connected to a control signal.

8. The memory circuit of claim 7, wherein the control signal is provided at a first logic state during the first clock pulse, the time difference, and the second clock pulse, and the control signal is provided at a second logic state during other time period different from the first clock pulse, the time difference, or the second clock pulse.

9. The memory circuit of claim 1, wherein the plurality of transistors include a transmission gate connected to an output of a last stage of the plurality of inverters, and wherein the transmission gate has a p-type transistor with its gate terminal connected to VSS and an n-type transistor with its gate terminal connected to VDD.

10. The memory circuit of claim 1, wherein the pre-charge signal has a pulse width determined based on the time difference.

11. The memory circuit of claim 1, wherein the delay circuit further includes a plurality of metal lines, each of which has a length proportional to a height of the memory array.

12. The memory circuit of claim 1, wherein the delay circuit further includes a plurality of metal lines, each of which has a length proportional to a width of the memory array.

13. A memory circuit, comprising:
a delay circuit configured to receive a first clock pulse and delay the first clock pulse as a second clock pulse, wherein the first clock pulse and the second clock pulse are within one clock cycle;
wherein the delay circuit includes a plurality of inverters and a plurality of transistors, and the plurality of transistors are configured such as to delay a rising edge of the second clock pulse that follows a falling edge of the first clock pulse in accordance with an increasing age of the memory circuit.

14. The memory circuit of claim 13, wherein the plurality of transistors include p-type transistors connected to even-numbered stages of the plurality of inverters, and wherein respective gate terminals of the p-type transistors are connected to VSS.

15. The memory circuit of claim 13, wherein the plurality of transistors include p-type transistors connected to even-numbered stages of the plurality of inverters and n-type transistors connected to odd-numbered stages of the plurality of inverters, and wherein respective gate terminals of the p-type transistors are connected to VSS and respective gate terminals of the n-type transistors are connected to VDD.

16. The memory circuit of claim 13, wherein the plurality of transistors include a p-type transistor connected to a first stage of the plurality of inverters and an n-type transistor connected to an input of a second stage of the plurality of inverters, and wherein respective gate terminals of the p-type transistor and the n-type transistor are both connected to a control signal.

17. The memory circuit of claim 13, wherein the plurality of transistors include a transmission gate connected to an output of a last stage of the plurality of inverters, and wherein the transmission gate has a p-type transistor with its gate terminal connected to VSS and an n-type transistor with its gate terminal connected to VDD.

18. The memory circuit of claim 13, further comprising:
a logic gate configured to receive the first clock pulse and the second clock pulse, and provide a pre-charge signal by OR'ing the first clock pulse and the second clock pulse;
wherein the pre-charge signal is configured for pre-charging a plurality of bit lines, and the pre-charge signal has a pulse width determined based on a time difference between the first clock pulse and the second clock pulse.

19. A method, comprising:
receiving a first clock pulse configured for a first operation of a first memory cell within a memory array;
delaying the first clock pulse as a second clock pulse configured for a second operation of a second memory cell within the memory array, wherein the first clock pulse and the second clock pulse, that immediately follows a falling edge of the first clock pulse, are within one clock cycle;
pre-charging a first bit line coupled to the first memory cell and a second bit line coupled to the second memory cell; and
delaying a rising edge of the second clock pulse.

20. The method of claim 19, further comprising:
providing, between the first clock pulse and the second clock pulse, a pre-charge signal with a pulse width determined based on the falling edge of the first clock pulse and the rising edge of the second clock pulse;
wherein the pre-charge signal is configured for pre-charging all bit lines of the memory array.
